(19) United States
(12) Patent Application Publication
(10) Pub. No.: US 2026/0344005 A1
(43) Pub. Date: Oct. 29, 2026

(54) CONTINUOUS HIGH DOPANT CONCENTRATION IN EPITAXY REGIONS

(71) Applicant: Taiwan Semiconductor Manufacturing Co., Ltd., Hsinchu (TW)

(72) Inventors: Kun-Chuan Lee, Hsinchu (TW); Tsung-Hsi Yang, Zhubei City (TW); Yi-Fang Pai, Hsinchu (TW); Te-An Chiu, Hsinchu (TW); Tsz-Mei Kwok, Hsinchu (TW); Ming-Hua Yu, Hsinchu (TW); Chii-Horng Li, Zhubei City (TW)

(21) Appl. No.: 19/727,178

(22) Filed: Jul. 1, 2026

Related U.S. Application Data
(63) Continuation of application No. 19/066,686, filed on Feb. 28, 2025.
(60) Provisional application No. 63/723,669, filed on Nov. 22, 2024.

(51) Int. Cl. H10D 84/01; H10D 62/60; H10D 84/83

(52) U.S. Cl. CPC H10D 84/013; H10D 62/60; H10D 84/832

(57) ABSTRACT

A method includes forming a plurality of semiconductor nanostructures. Upper ones of the plurality of semiconductor nanostructures overlap respective lower ones of the plurality of semiconductor nanostructures. The method further includes forming a source/drain recess aside of the plurality of semiconductor nanostructures, wherein the source/drain recess has a middle vertical line. A first semiconductor layer is formed from the plurality of semiconductor nanostructures, wherein the first semiconductor layer has a dopant of a conductivity type, and the conductivity type is p-type or n-type. A second semiconductor layer is formed over the first semiconductor layer, wherein the second semiconductor layer has a vertical-and-elongated high-dopant region aligned to the middle vertical line. A silicide region is formed over and electrically coupling to the second semiconductor layer.

### PRIORITY CLAIM AND CROSS-REFERENCE

This application is a continuation of U.S. patent application Ser. No. 19/066,686, filed Feb. 28, 2025, and entitled “CONTINUOUS HIGH DOPANT CONCENTRATION IN EPITAXY REGIONS,” which claims the benefit of U.S. Provisional Application No. 63/723,669, filed on Nov. 22, 2024, and entitled “CONTINUOUS HIGH PHOSPHORUS IN BULK NEPI,” which application are hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 20-22 illustrate the views of intermediate stages in the formation of a Gate All-Around (GAA) transistor in accordance with some embodiments.

FIGS. 15-19 illustrate the views of intermediate stages in the formation of a source/drain region in accordance with alternative embodiments.

FIGS. 23-24 illustrate the views of intermediate stages in the formation of a source/drain region in accordance with alternative embodiments.

FIG. 25 illustrates a process flow for forming a GAA transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All-Around (GAA) transistor and the formation methods are provided. In accordance with some embodiments, the formation of a source/drain region of the GAA transistor includes forming a first epitaxy layer, and a second epitaxy layer over the first epitaxy layer. The first epitaxy layer has a lower dopant concentration of a dopant (such as phosphorous or boron) and possibly a lower germanium atomic percentage than the second epitaxy layer. An elongated high-dopant region is formed in the middle of the second epitaxy layer and has a high dopant concentration. Accordingly, a low-resistance path is formed for the plurality of channels of the GAA transistors. The source/drain resistance is thus reduced.

Although GAA transistors are used as an example to discuss the concept of the present disclosure, the embodiments may be applied on other types of transistors including and not limited to planar transistors, Fin Field-Effect Transistors (FinFETs), Complementary Field-Effect Transistors (CFETs), and the like. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

In addition, although an n-type transistor may be discussed as an example in some parts of the discussion, and phosphorous is used as the example n-type dopant, the concept of the present application is readily available for the formation of p-type transistors, with the conductivity types of the corresponding features inversed than in the n-type transistor.

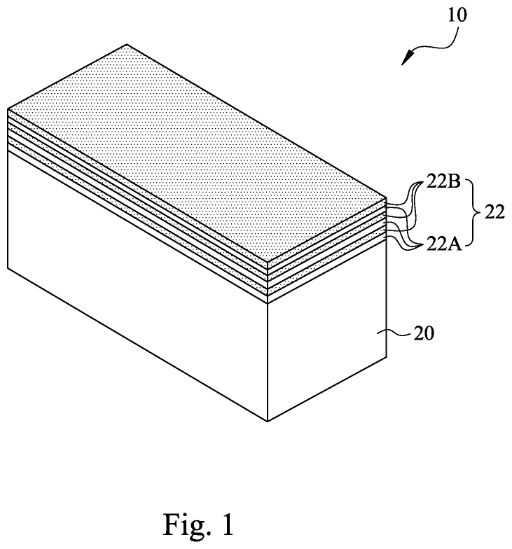

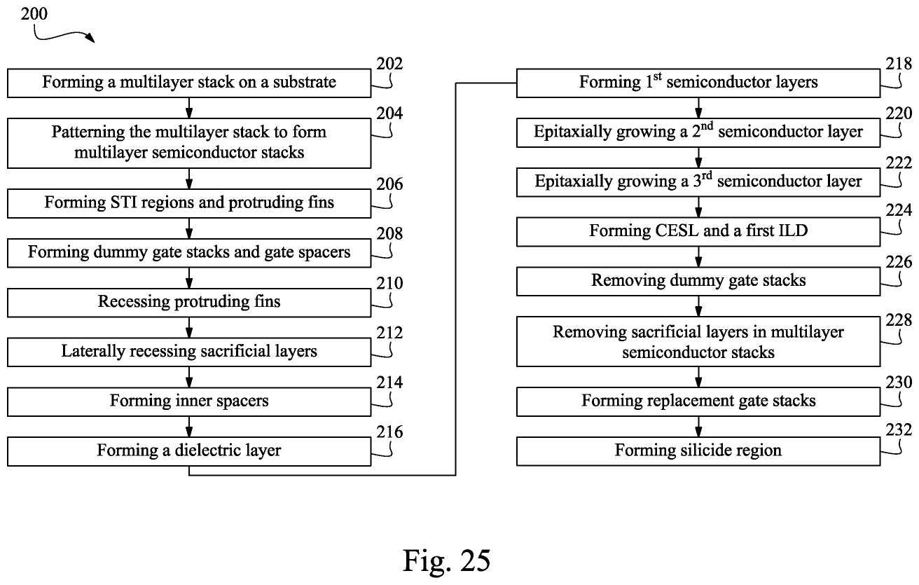

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 15-22 illustrate the cross-sectional views of intermediate stages in the formation of a GAA transistor in accordance with some embodiments of the present disclosure. The corresponding processes are also reflected schematically in the process flow shown in FIG. 25.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor substrate, although in other embodiments, it may be doped as an n-type semiconductor substrate.

In accordance with some embodiments, multilayer stack 22 is formed through a series of deposition processes for depositing alternating materials. The respective process is illustrated as process 202 in the process flow 200 shown in FIG. 25. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may include Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

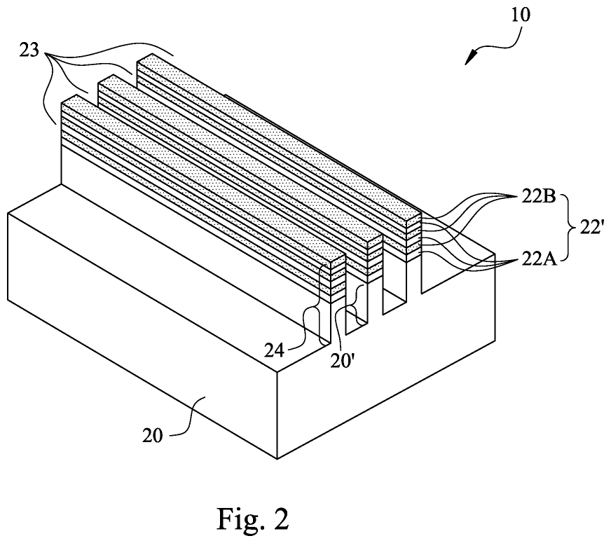

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 25. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

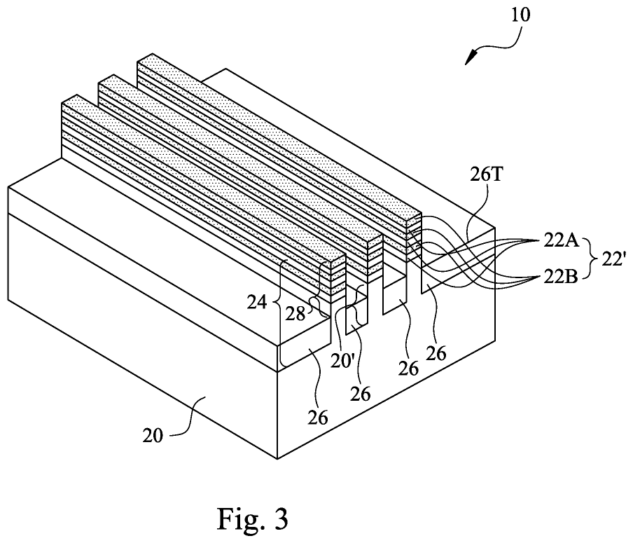

FIG. 3 illustrates the formation of isolation regions 26, which are also referred to as Shallow Trench Isolation (STI) regions throughout the description. The respective process is illustrated as process 206 in the process flow 200 shown in FIG. 25. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

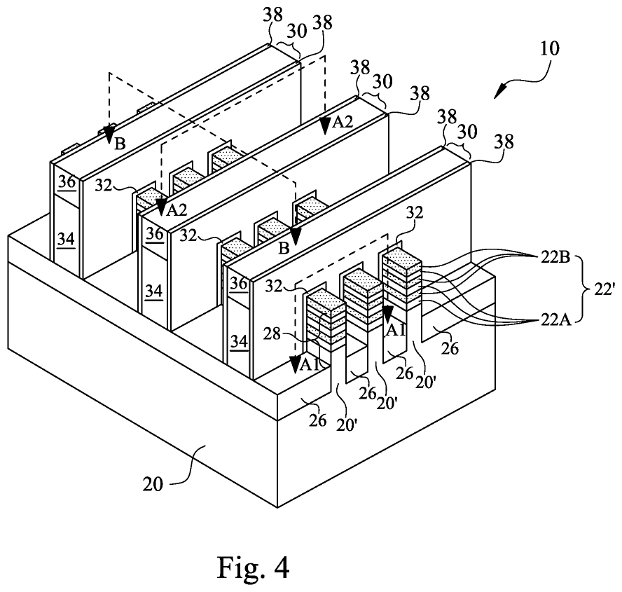

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 25. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbonitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

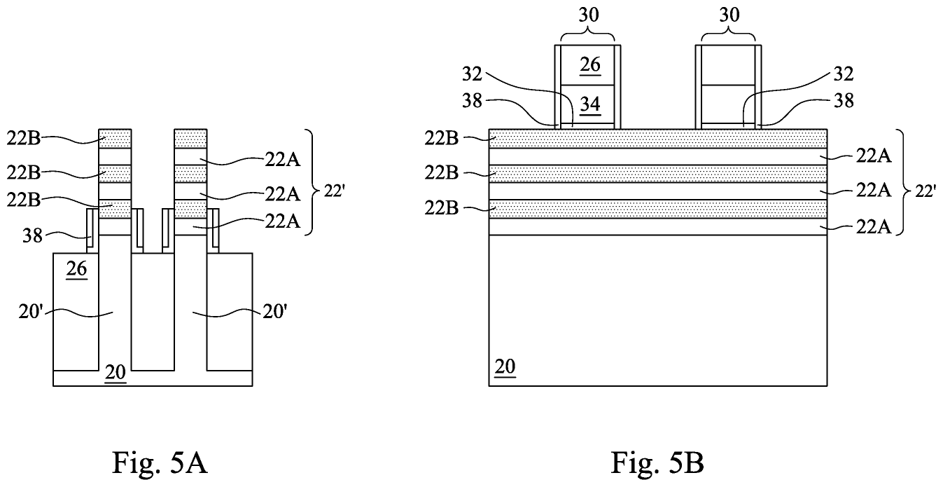

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by dummy gate stacks 30 and gate spacers 38, and is perpendicular to the gate-length direction. FIG. 5B illustrates the reference cross-section B-B in FIG. 4, which reference cross-section is parallel to the lengthwise directions of protruding fins 28.

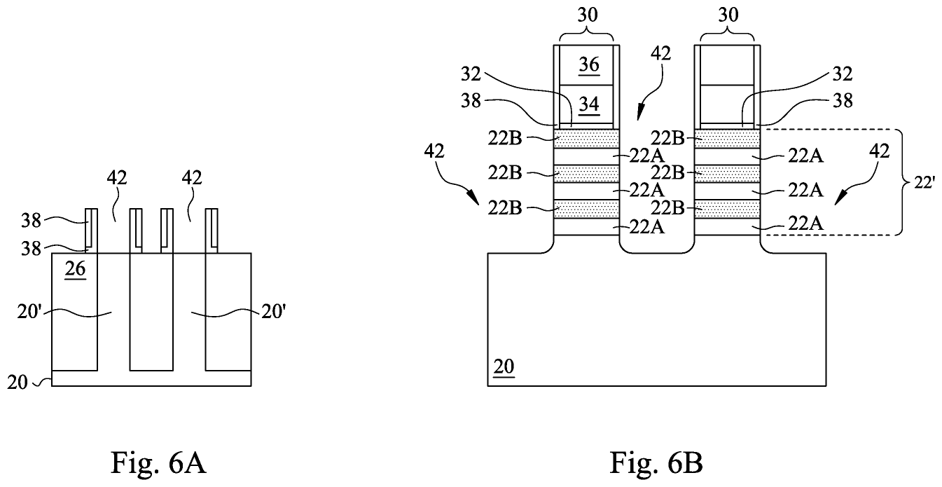

Referring to FIGS. 6A and 6B, the portions of protruding fins 28 (FIG. 4) that are not directly underlying dummy gate stacks 30 and gate spacers 38 are recessed through an etching process to form recesses 42. The respective process is illustrated as process 210 in the process flow 200 shown in FIG. 25. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

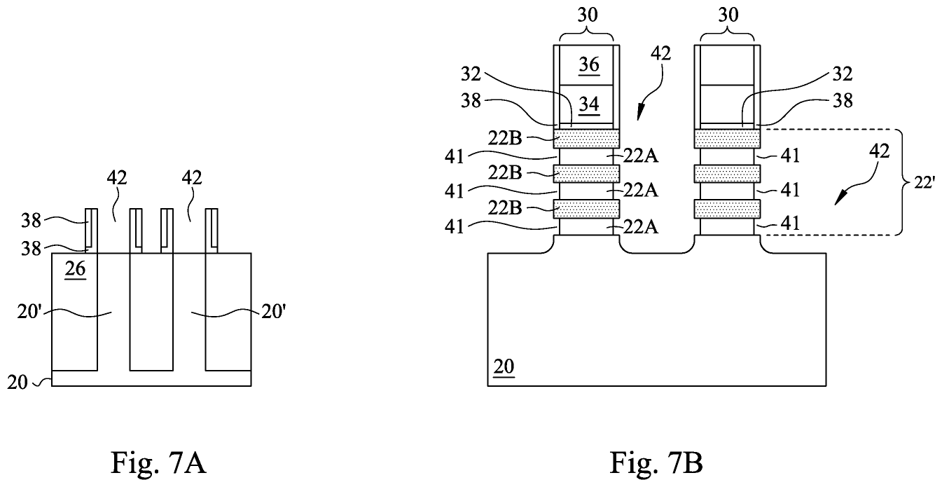

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown in FIG. 25.

The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

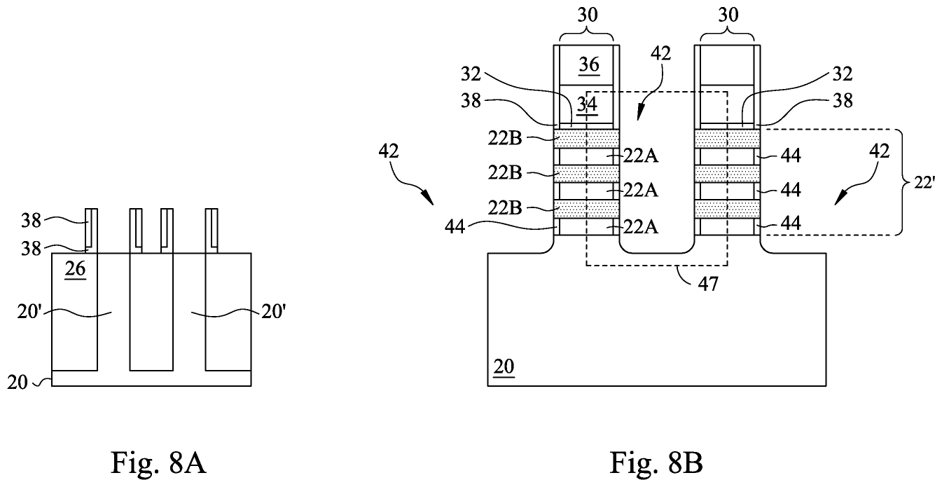

Referring to FIGS. 8A and 8B, inner spacers 44 are formed. The respective process is illustrated as process 214 in the process flow 200 shown in FIG. 25. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44. Inner spacers may be single-layer spacers, or may include a plurality of sub layers (such as two to three sub layers).

In accordance with alternative embodiments, inner spacers 44 are not formed, and the subsequently formed source/drain regions may be in contact with the high-k dielectric layers in the replacement gate stacks.

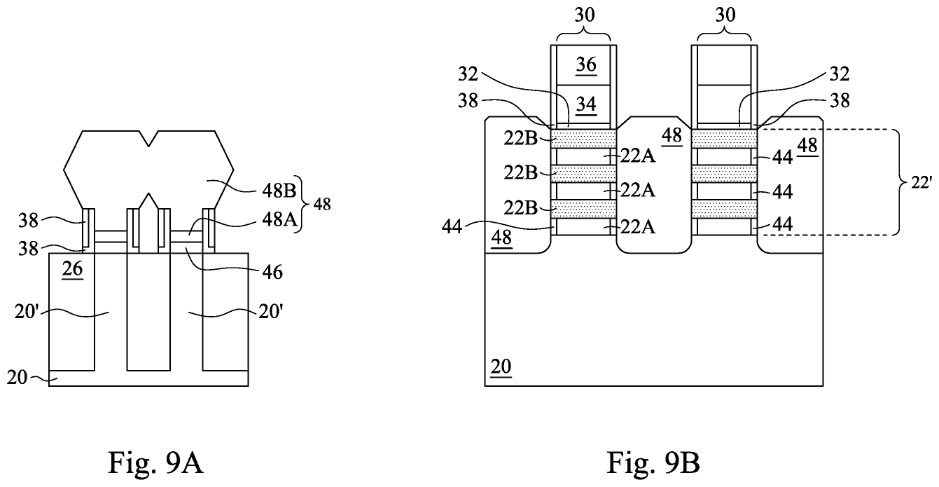

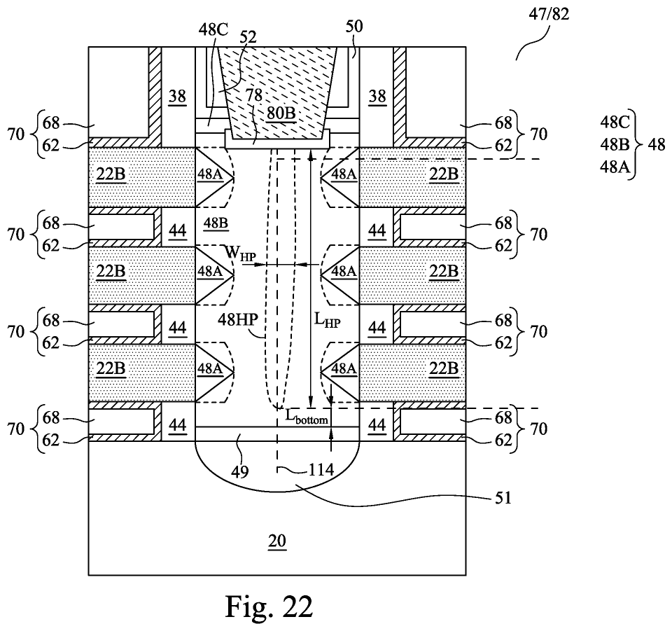

Referring to FIGS. 9A and 9B, source/drain regions 48 are formed in recesses 42, for example, through epitaxy processes. The details of source/drain regions 48 are illustrated in FIG. 22-24 in accordance with some embodiments.

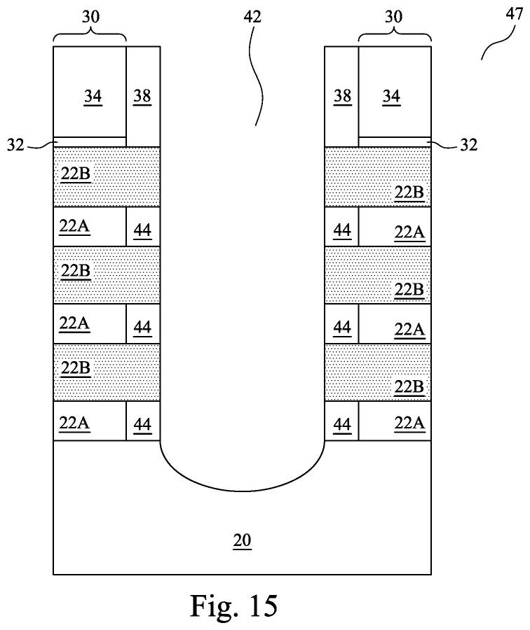

FIGS. 15-19 illustrate the details in the formation of source/drain regions 48 in accordance with some embodiments. FIG. 15 illustrates an amplified view of the region 47 in FIG. 8B, in which recesses 42 and inner spacers 44 have been formed. In the example as shown in FIG. 15, three stacked nanostructures 22B are illustrated as an example. The number of nanostructures 22B in a stack may be any other number, for example, ranging from 2 to about 5.

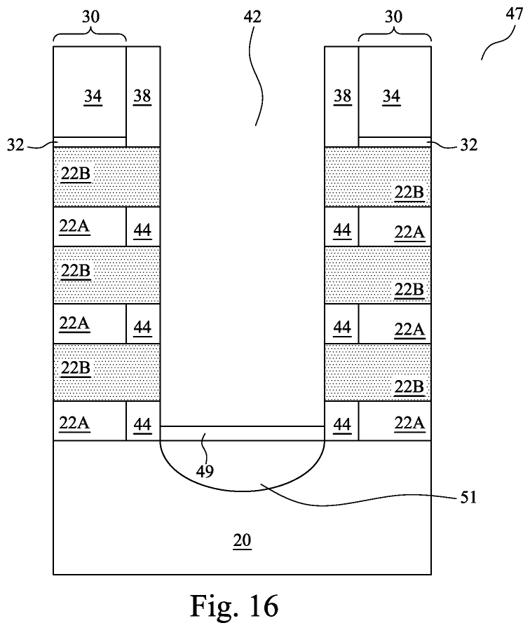

Referring to FIG. 16, dielectric layer 49 is formed at the bottom of recess 42. In some embodiment, an interposing layer 51 may be formed in between dielectric layer 49 and substrate 20. In some embodiment, the interposing layer may be an undoped or unintentional doped silicon, SiGe, and the like. The respective process is illustrated as process 216 in the process flow 200 shown in FIG. 25. In accordance with some embodiments, dielectric layer 49 comprises a silicon nitride layer. Dielectric layer 49 may have a single-layer structure including a single layer, or a multilayer structure including a plurality of dielectric layers formed of different dielectric materials. The material of dielectric layer 49 may be selected from silicon oxide, silicon nitride, silicon carbide, silicon oxynitride, or the like, and combinations thereof.

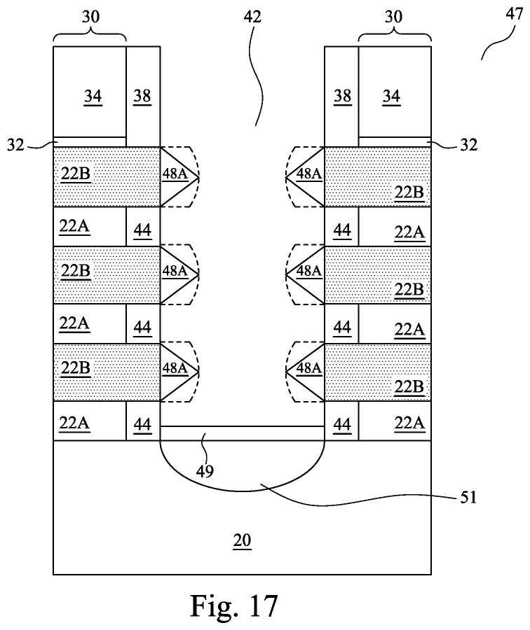

FIG. 17 illustrates the epitaxy of semiconductor layers 48A (also referred to as layer-1 or L1) through a selective epitaxy process. The respective process is illustrated as process 218 in the process flow 200 shown in FIG. 25. The resulting semiconductor layers 48A are selectively grown from the exposed sidewall surfaces of nanostructures 22B. The illustrated semiconductor layers 48A that are grown from opposite sides and grown toward each other are alternatively referred to as first portions and second portions of a semiconductor layer(s) 48A.

In FIG. 17, semiconductor layers 48A may be formed as having triangular shapes. In accordance with alternative embodiments, semiconductor layers 48A may have the shapes as indicated by the dashed lines, which have parallel upper and lower surfaces.

In accordance with some embodiments in which the source/drain region is an n-type region of an n-type transistor, semiconductor layers 48A may comprise Si, SiC, or the like, and further includes an n-type dopant such as phosphorous, arsenic, antimony, or combinations thereof. For example, semiconductor layers 48A may comprise SiP or SiCP.

During the epitaxy process, a silicon-containing precursor such as silane (SiH₄), di-silane (Si₂H₆), dichlorosilane (DCS, SiH₂Cl₂), Monomethylsilane (MMS) or the like, or combinations thereof, may be used as a deposition precursor. In accordance with some embodiments, the flow rate of silane may be greater than 0 sccm, and in the range between about 0 sccm and about 150 sccm. The flow rate of dichlorosilane may be in the range between about 100 sccm and about 900 sccm. The flow rate of MMS may be in the range between about 0 sccm and about 150 sccm. When both of silane and dichlorosilane are used, the dichlorosilane may have a greater flow rate than silane, and the reason will be discussed subsequently in the discussion of the formation of semiconductor layers 48B.

A carrier gas such as H₂, N₂, or their combination may be used. The flow rate of H₂ and/or N₂ may be lower than about 20 slm. An etching gas such as HCl, Cl₂, or the like may be added to make the deposition of semiconductor layer 48A selective, so that semiconductor layer 48A is grown starting from nanostructure 22B, but not from dielectric materials. The formation of semiconductor layer 48A may be achieved through CVD, Plasma Enhanced Chemical Vapor Deposition (PECVD), or the like. The pressure of the deposition chamber may be in the range between about 50 Torr and about 200 Torr. The wafer temperature may be in the range between about 650 °C and about 750 °C.

When the respective transistor is an n-type transistor, semiconductor layer 48A may comprise an n-type dopant such as phosphorous, arsenic or the like. The n-type dopant concentration may also be in the range between about 0/cm³ and about 4E21/cm³, and may be in the range between about 4E20/cm³ and about 7E20/cm³. The atomic percentage of the n-type dopant may be in the range between about 0 percent and about 5 percent, and may be in the range between about 0 percent and about 1 percent. The arsenic (if adopted) concentration may be in the range between about 1E19/cm³ and about 1E21/cm³. The carbon (if adopted) concentration may be in the range between about 1E19/cm³ and about 4E21/cm³.

The precursor of phosphorous may comprise phosphine (PH₃), and the flow rate may be in the range between about 30 sccm and about 270 sccm. The precursor of arsenic may comprise AsH₃, and the flow rate may be in the range between about 30 sccm and about 270 sccm. The flow rate of SbH₃, if used (which may be used in a p-type transistor), may be in the range between about 0 sccm and about 360 sccm. The flow rate of HCl (etching gas) may be in the range between about 30 sccm and about 600 sccm. The flow rate of Cl₂ (etching gas) may be in the range between about 10 sccm and about 300 sccm.

When the source/drain region is a p-type region of a p-type transistor, semiconductor layers 48A may comprise silicon, SiGe, or Ge, and further includes a p-type dopant such as boron, indium, or combinations thereof. For example, semiconductor layers 48A may comprise SiGe, with boron being doped. The semiconductor layers 48A may have a p-type dopant concentration in a range between about 4E20/cm³ and about 7E20/cm³. The germanium atomic percentage may be in the range between about 0 percent and about 40 percent.

In accordance with some embodiments, there may be a plurality of discrete semiconductor layers 48A that are separated from each other, each epitaxially grown from one of nanostructures 22B. The semiconductor layers 48A may have similar (and/or the same) sizes and shapes. This may help the simultaneous merging of semiconductor layers 48B. Also, the upper ones of the semiconductor layers 48A may have the same sizes, and extend laterally into recess 42 for same or similar distances, as the respective lower ones of the semiconductor layers 48A. Due to the lower growth rate in (111) directions, semiconductor layers 48A may have facets.

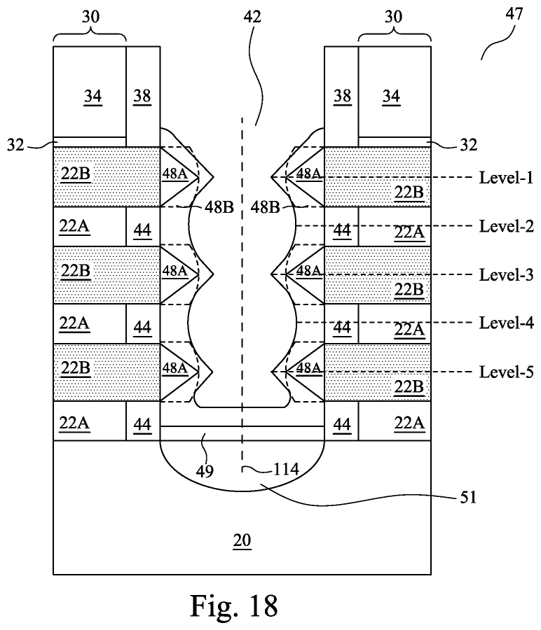

In accordance with some embodiments, the semiconductor layers 48A that are grown from different nanostructures 22B are separated from each other when the formation of semiconductor layers 48B (FIG. 18) is started. In accordance with alternative embodiments, the portions of the semiconductor layers 48A grown from different nanostructures 22B are merged when the formation of semiconductor layers 48B (FIG. 18) is started.

FIG. 18 illustrates the epitaxy growth of semiconductor layer 48B (also referred to as semiconductor layer-2 or L2). The respective process is illustrated as process 220 in the process flow 200 shown in FIG. 25. The resulting semiconductor layer 48B is grown from semiconductor layers 48A. In accordance with some embodiments, semiconductor layer 48B has a higher n-type dopant (such as phosphorous) or p-type dopant (such as boron) concentration than semiconductor layers 48A.

In accordance with some embodiments, semiconductor layers 48B may comprise similar or same material as that of semiconductor layers 48A. For example, semiconductor layers 48B may comprise Si, SiC, or the like, and further includes an n-type dopant such as phosphorous, arsenic, antimony, or combinations thereof.

When the respective transistor is an p-type transistor, semiconductor layer 48B may comprise SiGe with a germanium atomic percentage higher than the germanium atomic percent of semiconductor layers 48A. For example, the germanium atomic percentage in semiconductor layer 48B may be in the range between about 40 percent and about 90 percent, while the germanium atomic percentage in semiconductor layer 48A may be in the range between about 0 percent and about 40 percent.

During the epitaxy process, a silicon-containing precursor such as silane (SiH₄), di-silane (Si₂H₆), dichlorosilane (SiH₂Cl₂), Monomethylsilane (MMS) or the like, or combinations thereof, may be used as a deposition precursor. In accordance with some embodiments, the flow rate of silane may be in the range between about 0 sccm and about 150 sccm. The flow rate of dichlorosilane may be in the range between about 100 sccm and about 900 sccm. The flow rate of MMS may be in the range between about 0 sccm and about 150 sccm. The germane (GeH₄, if contained, for example, when forming a p-type source/drain region) may have a flow rate in the range between about 0 sccm and about 150 sccm.

A carrier gas such as H₂, N₂, or the combination may be used. The flow rate of H₂ may be lower than about 20 slm. The flow rate of N₂ may be lower than about 15 slm. An etching gas such as HCl, Cl₂, or the like may be added. The formation of semiconductor layer 48B may be achieved through CVD, PECVD, or the like. The pressure of the deposition chamber may be in the range between about 50 Torr and about 200 Torr. The wafer temperature may be in the range between about 650 °C and about 780 °C.

When the respective transistor is an n-type transistor, semiconductor layer 48B may comprise an n-type dopant such as phosphorous, arsenic or the like. The phosphorous concentration may be in the range between about 1E19/cm³ and about 4E21/cm³. The atomic percentage of the n-type dopant may be in the range between about 1 percent and about 20 percent, and may be in the range between about 3 percent and about 10 percent. The arsenic (if adopted) concentration may be in the range between about 1E19/cm³, and about 1E21/cm³. The carbon (if adopted) concentration may be in the range between about 1E19/cm³, and about 4E21/cm³.

The precursor of phosphorous may comprise PH₃, and the flow rate may be in the range between about 30 sccm and about 270 sccm. The precursor of arsenic may comprise AsH₃, and the flow rate may be in the range between about 30 sccm and about 270 sccm. The flow rate of SbH₃ (if used, which may be used in a n-type transistor) may be in the range between about 0 sccm and about 360 sccm. The flow rate of HCl (etching gas) may be in the range between about 30 sccm and about 600 sccm. The flow rate of Cl₂ (etching gas) may be in the range between about 10 sccm and about 300 sccm.

In accordance with some embodiments, the precursor for forming semiconductor layers 48B may comprise one, two, or more silicon-containing precursors. The silicon-containing precursors may have sticking coefficients, which are the ratios of the numbers of adsorbate atoms (to surfaces they are in contact with) to the total numbers of atoms that impinge upon the surfaces. In accordance with some embodiments, silane has a greater sticking coefficient of about 4×10⁻³, and dichlorosilane (DCS, SiH₂Cl₂) has a smaller sticking coefficient of about 2.5×10⁻³.

With a silicon-containing precursor having a higher sticking coefficient, more molecules of the silicon-containing precursor may be attached to the upper nanostructures 22B than to respective lower ones of the nanostructures 22B. This causes the growth of semiconductor layers 48B from the upper semiconductor layers 48A to be faster than the growth of semiconductor layers 48B from the lower semiconductor layers 48A. This will adversely cause the high-dopant regions to be pushed to the bottom portion of the respective source/drain region, and the desirable effect of forming a vertical and elongated high-dopant region (as will be discussed in subsequent paragraphs) cannot be achieved.

Conversely, with a silicon-containing precursor having a smaller sticking coefficient, the number of molecules of the silicon-containing precursor attached to the upper nanostructures 22B and the number of molecules attached to lower ones of the nanostructures 22B are more uniform. This desirably causes the growth of semiconductor layers 48B at different levels (for example, from different ones of the semiconductor layers 48A (and nanostructures 22B) at different levels) to be close to or the same as each other, and a vertical elongated high-dopant region may be desirably formed.

The silicon-containing precursor comprises a first precursor with a lower sticking coefficient and a second precursor with a higher sticking coefficient. In subsequent discussion, the flow rate FR_{HSC} represents the flow rate of the high-sticking-coefficient silicon-containing precursor, and flow rate FR_{LSC} represents the flow rate of the low-sticking-coefficient silicon-containing precursor. In accordance with some embodiments, to achieve a more uniform growth of semiconductor layers 48B at different levels (such as levels level-1, level-2, level-3, level-4, and level-5 as shown in FIG. 18), the flow rate ratio FR_{HSC}/FR_{LSC} is smaller than 1, which means that the flow rate of the high-sticking-coefficient silicon-containing precursor is lower than the flow rate of the low-sticking-coefficient silicon-containing precursor.

The flow rate ratio FR_{HSC}/FR_{LSC} for achieving the uniform growth of semiconductor layers 48B is related to the types of silicon-containing precursors. For example, when the mixture of silane and DCS is used, the flow rate ratio FR_{HSC}/FR_{LSC} may be smaller than about 0.7, and may be in the range between about 0 and about 0.7. With the flow rate ratio FR_{HSC}/FR_{LSC} being in this range, the growth rate of semiconductor layers 48B at levels level-1, level-3, and level-5 may be equal to each other, and the growth rate of semiconductor layers 48B at levels level-2 and level-4 may be equal to each other.

It is also desirable that the silicon-containing precursor includes both of a low-sticking-coefficient silicon-containing precursor and a high-sticking-coefficient silicon-containing precursor. Using two or more silicon-containing precursors (such as silane and DCS) with different sticking coefficients and proper flow rate ratio FR_{HSC}/FR_{LSC} may improve the overall profile of semiconductor layers 48B, and may also result in the formation of the elongated vertical high-doping region 48HP.

In order for the semiconductor layers 48B at different levels to merge at a similar time point, the plurality of semiconductor regions 48A are also preferred to have the same size. Otherwise, the difference in the size of semiconductor regions 48A will also adversely affect the merging time of semiconductor regions 48B. In accordance with some embodiments, the flow rate ratio FR_{HSC}/FR_{LSC} for forming semiconductor regions 48A may be in similar range, and may be the same as or different from the flow rate ratio FR_{HSC}/FR_{LSC} for forming semiconductor regions 48B.

During the epitaxy of semiconductor layers 48B, the dopant (such as phosphorous) atomic percentage is highest at the exposed surfaces of semiconductor layers 48B. With the proceeding of the growth, the surfaces of the semiconductor layers 48B having the highest phosphorous atomic percentage is grown toward the middle vertical line 114 of recess 42. When the surfaces of the semiconductor layers 48B on the left side of middle vertical line 114 are merged with the surfaces of the semiconductor layers 48B on the right side of middle vertical line 114, at the merging points, the phosphorous atomic percentage are the highest. Since the merging points are aligned to the middle vertical line 114, a vertical and elongated high-dopant (such as phosphorous) region is generated along the middle vertical line 114.

It is appreciated that if the flow rate ratio FR_{HSC}/FR_{LSC} is high, for example, higher than about 0.7, or even higher than about 1, at level level-1, the growth rate is the highest, and the growth rate at lower levels are lower. This causes the merging to occur at level level-1 first, followed by the merging at lower levels such as levels level-3 and level-5 and levels level-2 and level-4. This causes the merging to proceed from top to bottom, and hence the high-phosphorus region is limited to the lower part of the resulting source/drain region. This causes the resistance of the source/drain region to be high.

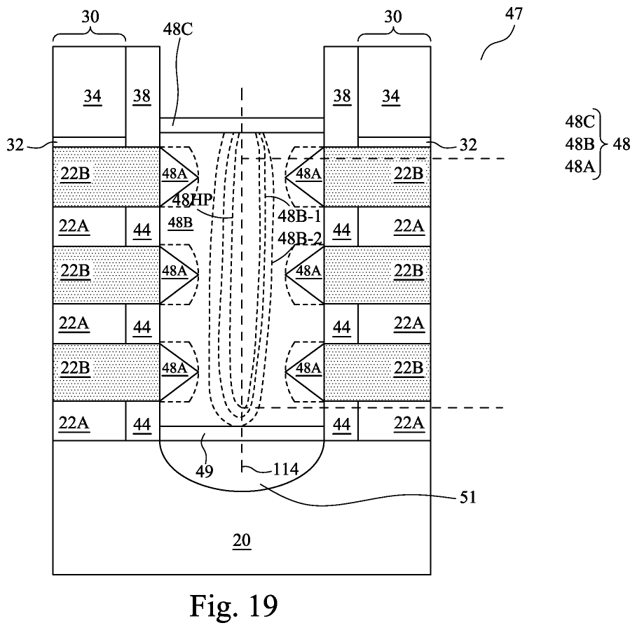

In accordance with some embodiments, with the low flow rate ratio FR_{HSC}/FR_{LSC}, when the formation of semiconductor layers 48B is finished, as shown in FIG. 19, a high-doping region 48HP is generated along the middle vertical line 114. In accordance with some embodiments, the minimum doping atomic percentage of high-doping region 48HP is represented as DPH, and the lowest doping atomic percentage of semiconductor layers 48B is represented as DPL. The lowest doping atomic percentage may occur at the interface between semiconductor layers 48B and semiconductor layers 48A, or in other places. The high-doping region 48HP may be considered as the regions have doping atomic percentage ratio DPH/DPL being greater than certain value, which may be 1.5. The doping atomic percentage ratio DPH/DPL may be in the range between about 4 and about 20.

In accordance with some embodiments when phosphorous is doped, high-doping region 48HP (which is interchangeably referred to as a high-dopant region) may also be considered as the regions with phosphorous atomic percentage being equal to or greater than 4 percent, and with doping atomic percentage ratio DPH/DPL being greater than 1.5 (and possibly between about 4 and about 20). The rest portions of semiconductor layers 48B and the entirety of semiconductor layers 48A have dopant concentrations (and atomic percentage) lower than that in high-doping region 48HP. Doping region 48B-1 and 48B-2 illustrate some example regions with the dopant atomic percentages increasingly lower than that in high-doping region 48HP, but higher than the rest of semiconductor layers 48B and 48A.

In accordance with some embodiments, to ensure a continuous high-doping region 48HP is formed, at the time the semiconductor layers 48B at levels level-1, level-3, and level-5 on opposite sides of middle vertical line 114 start to merge, the flow rate of the dopant-containing precursor (such as PH₃) is increased, for example, by 20 percent, 50 percent, or 100 percent over that for the preceding formation of semiconductor layers 48B. The increase of the flow rate of the dopant-containing precursor and/or the reduction of the flow rate of the silicon-containing precursor will increase the dopant atomic percentage at the merging interfaces and help the formation of the high-dopant region 48HP.

FIG. 19 further illustrates the formation of semiconductor layer (capping layer) 48C in accordance with some embodiments, for example, through a selective epitaxy process. The respective process is illustrated as process 222 in the process flow 200 shown in FIG. 25. In accordance with some embodiments, capping layer 48C comprises silicon and is free from germanium. Capping layer 48C may also include SiGe with a lower germanium atomic percentage than that in semiconductor layers 48A and 48B. The phosphorous (or boron) concentration in capping layer 48C may also be lower than or equal to that in semiconductor layer 48B. In accordance with alternative embodiments, capping layer 48C is not formed. Throughout the description, semiconductor layers 48A, 48B, and 48C are collectively referred to as source/drain regions 48.

The high-dopant region 48HP may be used as a low-resistance conductive path for conducting the currents flowing between nanostructures 22B and the overlying silicide region 78 (FIG. 22). In order for the bottom ones of the nanostructures 22B to be connected to the low-resistivity path with a small distance, the bottom of high-dopant region 48HP may be level with or lower than the top surface of the bottom one of the nanostructures 22B, and more preferably level with or lower than the bottom surface of the bottom one of the nanostructures 22B. The top end of the high-dopant region 48HP is as high as possible, for example, level with or higher than the bottom surface of the top one of the nanostructures 22B, or level with or higher than the top surface of the top one of the nanostructures 22B. This allows the high-dopant region 48HP to be as close to, or even joined to, the silicide region 78 (FIG. 22), so that the source/drain resistance is reduced.

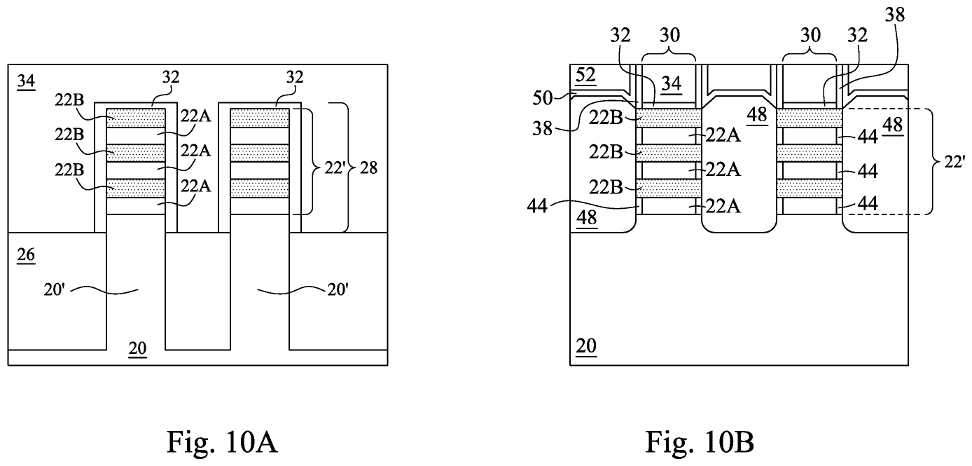

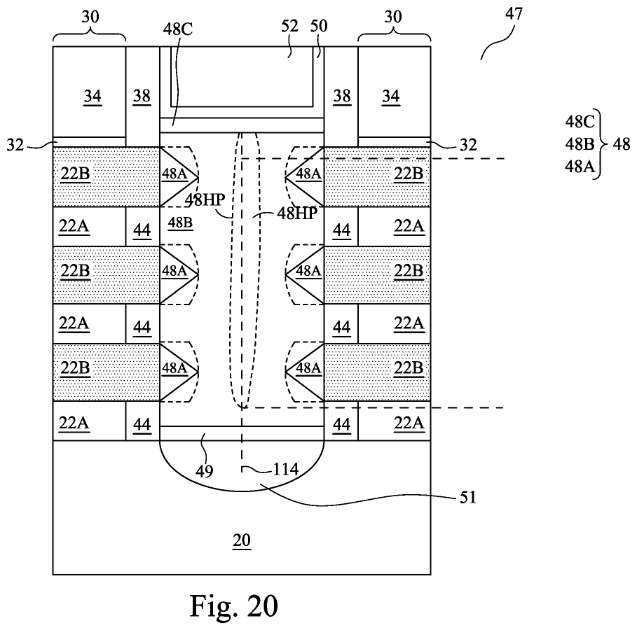

Referring back to FIGS. 10A and 10B, Contact Etch Stop Layer (CESL) 50 and Inter-Layer Dielectric (ILD) 52 are formed. The respective process is illustrated as process 224 in the process flow 200 shown in FIG. 25. The corresponding structure is also shown in FIG. 20. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

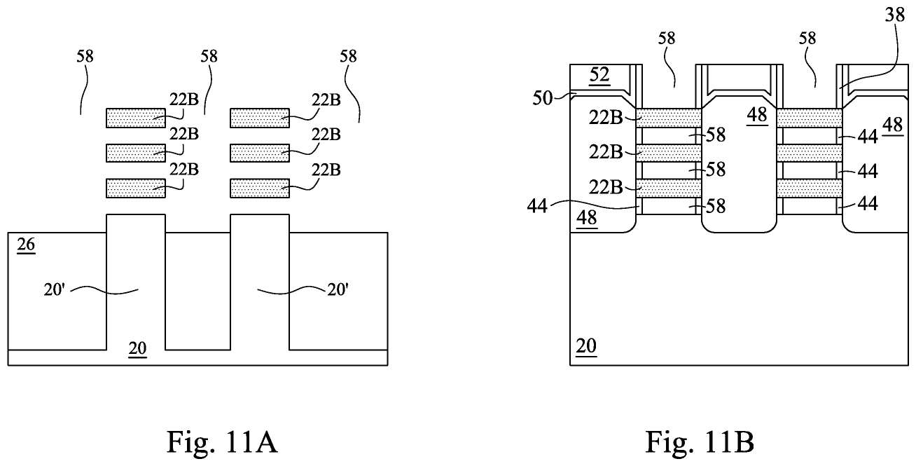

Next, dummy gate electrodes 34 and dummy gate dielectrics 32 (and hard masks 36, if remaining) are removed in one or more etching processes, so that recesses are formed, as shown in FIGS. 11A and 11B. The respective process is illustrated as process 226 in the process flow 200 shown in FIG. 25.

Sacrificial layers 22A are then removed to extend recesses 58 between nanostructures 22B. The respective process is illustrated as process 228 in the process flow 200 shown in FIG. 25. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A.

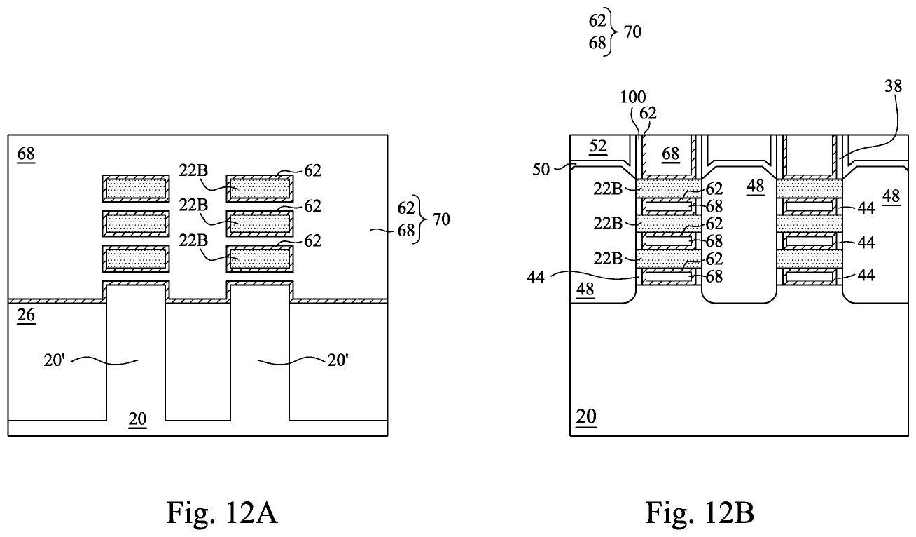

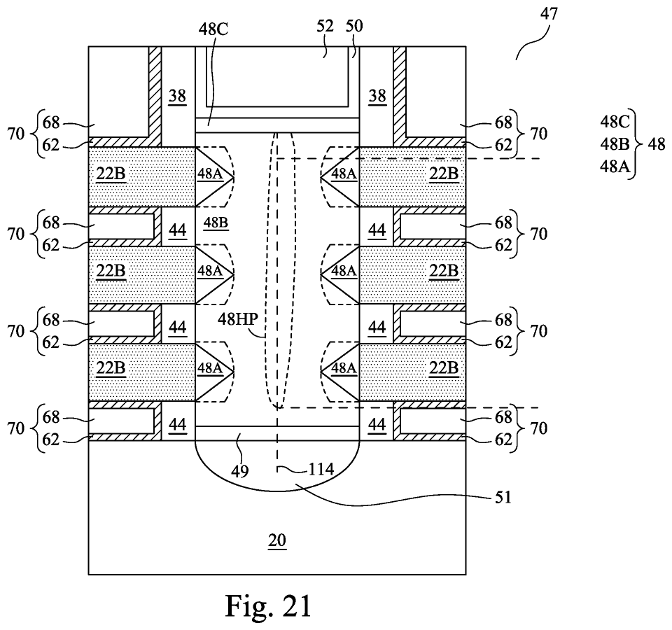

Referring to FIGS. 12A and 12B, gate dielectrics 62 and gate electrodes 68 are formed, hence forming replacement gate stacks 70. The respective process is illustrated as process 230 in the process flow 200 shown in FIG. 25. The corresponding structure is also shown in FIG. 21. In accordance with some embodiments, each of gate dielectric 62 includes an interfacial layer and a high-k dielectric layer on the interfacial layer. The interfacial layer may be formed of or comprise silicon oxide. In accordance with some embodiments, the high-k dielectric layer comprises one or more dielectric layers. For example, the high-k dielectric layer may include a metal oxide or a silicate of hafnium, aluminum, zirconium, lanthanum, manganese, barium, titanium, lead, and combinations thereof.

Gate electrodes 68 are also formed. In the formation process, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof.

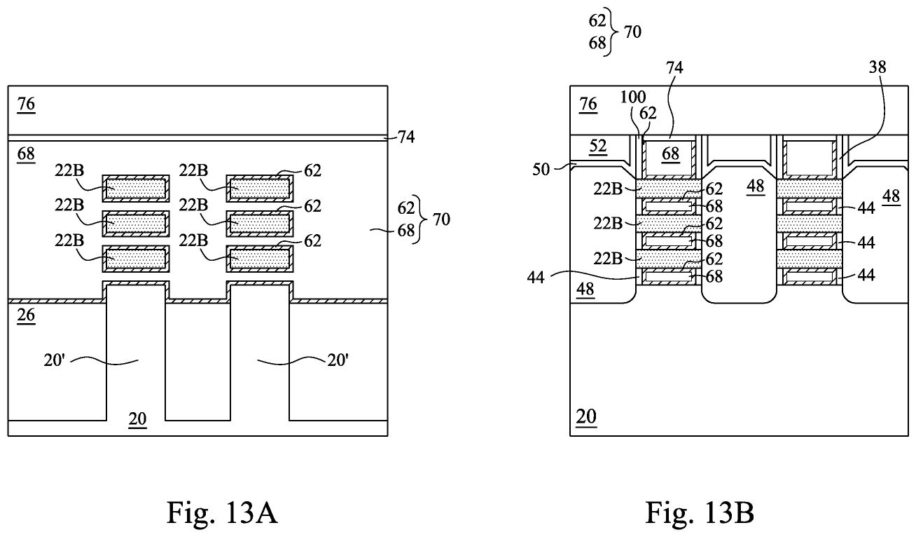

In the processes shown in FIGS. 13A and 13B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 13A and 13B, ILD 76 is deposited over ILD 52 and over gate masks 74. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

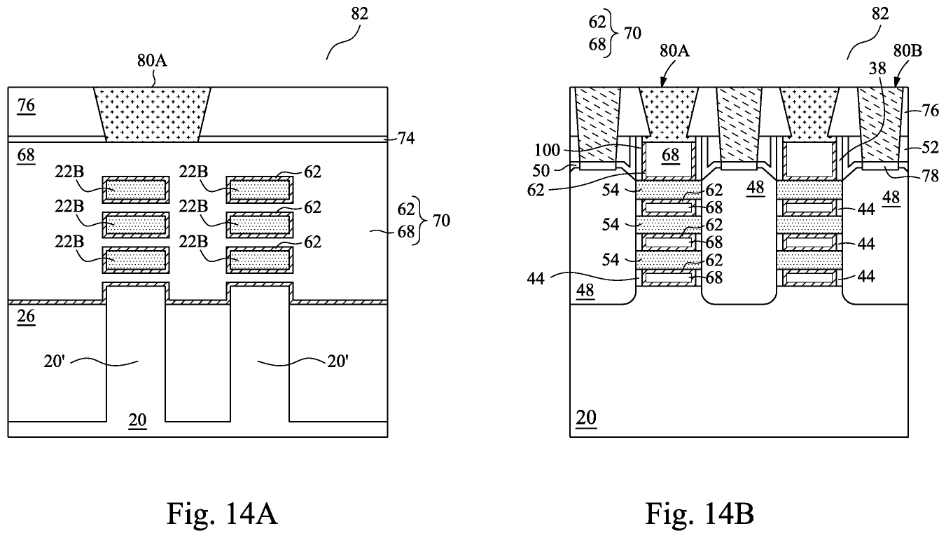

In FIGS. 14A and 14B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process, such as RIE, NBE, or the like. Although FIG. 14B illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. The respective process is illustrated as process 232 in the process flow 200 shown in FIG. 25. Contact plugs 80B are then formed over silicide regions 78. Also, contact plugs 80A (may also be referred to as gate contact plugs) are also formed in the recesses, and are over and contacting gate electrodes 68. The corresponding structure is also shown in FIG. 22. Transistor 82 is thus formed.

FIG. 22 illustrates parts of the transistor 82, which is also shown in FIGS. 14A and 14B. In accordance with some embodiments, the high-dopant region 48HP is elongated and has lengthwise direction along center line 114. The high-dopant region 48HP has height L_{HP}, width W_{HP}, and bottom distance L_{bottom} from dielectric layer 49. Height L_{HP} may be in the range between about 10 nm and about 40 nm. Width W_{HP} may be in the range between about 1.5 nm and about 30 nm. Bottom distance L_{bottom} may be in the range between about 3 nm and about 15 nm. The top end of the high-dopant region 48HP may be in physical contact with or lower than silicide region 78.

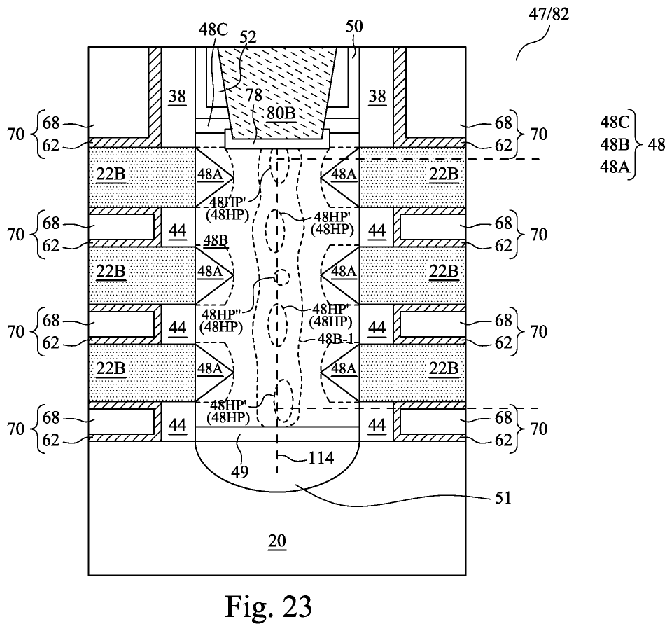

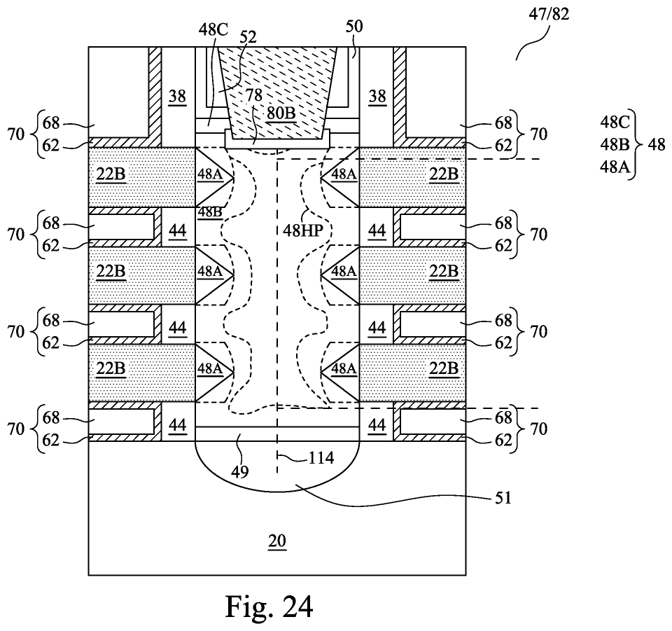

FIGS. 23 and 24 illustrate a portion of the GAA transistor 82 in accordance with alternative embodiments. Unless specified otherwise, the materials, the structures, and the formation processes of the components in these embodiments (and subsequent embodiments) are essentially the same as the like components denoted by like reference numerals in the preceding embodiments.

The structure as shown in FIG. 23 is essentially the same as the preceding embodiments, except that the high-dopant region 48HP may include a plurality of discrete portions separated from each other by doping region 48B-1. The dopant concentration of doping region 48B-1 is lower than that in high-dopant region 48HP, but higher than the rest of the source/drain region 48. In accordance with some embodiments, all of the discrete portions overlap the middle vertical line 114, and collectively form a low-resistivity path. Furthermore, some portions (denoted as 48HP′) of high-dopant region 48HP have centers horizontally aligned to the middle levels of inner spacers 44. There may be, or may not be, other portions (denoted as portion 48HP″) of high-dopant region 48HP between portions 48HP′.

FIG. 24 illustrates the formation of high-dopant region 48HP in accordance with alternative embodiments. The high-dopant region 48HP has an elongated vertical portion, and a plurality of elongated horizontal portions partially overlapping the elongated vertical portion. The plurality of elongated horizontal portions are formed due to the merging of upper portions of semiconductor layers 48B to the respective lower portions of semiconductor layers 48B. The elongated horizontal portions may be horizontally aligned to, and extend toward, the middle level of inner spacers 44.

It is appreciated that semiconductor layers 48A may also have the shape as shown by dashed lines as shown in FIG. 18. When the phosphorus concentration in the middle of semiconductor layers 48A and subsequently formed epitaxy layers is high enough, the subsequent multiple processes performed after the epitaxy of semiconductor layers 48A (which multiple processes include thermal processes) may cause the phosphorus to diffuse outwardly. This may also result in the high-doping region 48HP to have the fishbone shape, as shown in FIG. 24.

The embodiments of the present disclosure have some advantageous features. By adjusting process conditions to form vertical elongated high-dopant regions, which have a low resistivity, low-resistance current paths are formed for currents flowing between channels and silicide regions (and source/drain contact plugs), the resistance of the source/drain region is reduced, and the performance of the resulting transistor is improved.

In accordance with some embodiments of the present disclosure, a method comprises forming a plurality of semiconductor nanostructures, wherein upper ones of the plurality of semiconductor nanostructures overlap respective lower ones of the plurality of semiconductor nanostructures; forming a source/drain recess aside of the plurality of semiconductor nanostructures, wherein the source/drain recess has a middle vertical line; forming a first semiconductor layer from the plurality of semiconductor nanostructures, wherein the first semiconductor layer comprises a dopant of a conductivity type, and the conductivity type is p-type or n-type; forming a second semiconductor layer over the first semiconductor layer, wherein the second semiconductor layer comprises a vertical-and-elongated high-dopant region aligned to the middle vertical line; and forming a silicide region over and electrically coupling to the second semiconductor layer.

In an embodiment, the forming the second semiconductor layer is performed using a precursor comprising: a first silicon-containing precursor having a first sticking coefficient; and a second silicon-containing precursor having a second sticking coefficient smaller than the first sticking coefficient. In an embodiment, the first silicon-containing precursor comprise silane, and the second silicon-containing precursor comprises dichlorosilane. In an embodiment, the forming the second semiconductor layer comprises doping phosphorous.

In an embodiment, the second semiconductor layer comprises a first portion and a second portion grown toward each other, and wherein the method comprises: before the first portion is merged with the second portion, conducting phosphine with a first flow rate; and at a time the first portion is merged with the second portion, conducting phosphine with a second flow rate greater than the first flow rate. In an embodiment, the plurality of semiconductor nanostructures comprise a topmost semiconductor nanostructure and a bottommost semiconductor nanostructure, and wherein a top end of the vertical-and-elongated high-dopant region is higher than a bottom surface of the topmost semiconductor nanostructure; and a bottom end of the vertical-and-elongated high-dopant region is lower than a top surface of the bottommost semiconductor nanostructure.

In an embodiment, the top end of the vertical-and-elongated high-dopant region is higher than a top surface of the topmost semiconductor nanostructure; and the bottom end of the vertical-and-elongated high-dopant region is lower than the bottom surface of the bottommost semiconductor nanostructure. In an embodiment, the vertical-and-elongated high-dopant region is spaced apart from the silicide region. In an embodiment, the vertical-and-elongated high-dopant region physically contacts the silicide region. In an embodiment, the vertical-and-elongated high-dopant region comprises a plurality of discrete portions aligned to the middle vertical line.

In accordance with some embodiments of the present disclosure, a method comprises forming a semiconductor stack comprising a plurality of semiconductor nanostructures; and forming a source/drain region comprising: epitaxially growing a first semiconductor layer comprising a first plurality of portions and a second plurality of portions, wherein the first plurality of portions and the second plurality of portions are grown toward each other; epitaxially growing a second semiconductor layer comprising a third plurality of portions over the first plurality of portions and a fourth plurality of portions over the third plurality of portions, wherein the growing the second semiconductor layer is performed using a process gas comprising: a first silicon-containing precursor having a first sticking coefficient; and a second silicon-containing precursor having a second sticking coefficient smaller than the first sticking coefficient, wherein the first silicon-containing precursor has a lower flow rate than the second silicon-containing precursor; epitaxially growing a third semiconductor layer over the first semiconductor layer; and forming a silicide region over and contacting the second semiconductor layer.

In an embodiment, a ratio of a first flow rate of the first silicon-containing precursor to a second flow rate of the second silicon-containing precursor is smaller than about 0.7. In an embodiment, the first silicon-containing precursor comprises silane, and the second silicon-containing precursor comprises dichlorosilane.

In an embodiment, the second semiconductor layer comprises a high-phosphorous region having an atomic percentage greater than about 4 percent, and the high-phosphorous region comprises a vertical-and-elongated portion extending from a first level of a topmost semiconductor nanostructure of the plurality of semiconductor nanostructures to a second level of a bottommost semiconductor nanostructure of the plurality of semiconductor nanostructures. In an embodiment, the high-phosphorous region has a height and a width smaller than the height. In an embodiment, the high-phosphorous region further comprises a plurality of elongated horizontal portions joined with the vertical-and-elongated portion.

In accordance with some embodiments of the present disclosure, a structure comprises a semiconductor stack comprising a plurality of semiconductor nanostructures, wherein the plurality of semiconductor nanostructures comprise: a topmost semiconductor nanostructure; and a bottommost semiconductor nanostructure overlapped by the topmost semiconductor nanostructure; a source/drain region aside of the semiconductor stack, the source/drain region comprising: a first semiconductor layer; and a second semiconductor layer between portions of the first semiconductor layer, wherein the second semiconductor layer comprises a high-dopant region, and the high-dopant region comprises a vertical-and-elongated portion extending from a first level of the topmost semiconductor nanostructure to a second level of the bottommost semiconductor nanostructure; a source/drain silicide region over and contacting the second semiconductor layer, wherein the source/drain silicide region is spaced apart from the first semiconductor layer; and a source/drain contact plug over and contacting the source/drain silicide region.

In an embodiment, the high-dopant region comprises phosphorous with an atomic percentage greater than about 4 percent. In an embodiment, the high-dopant region further comprises a plurality of horizontal portions joined with the vertical-and-elongated portion. In an embodiment, the vertical-and-elongated portion comprises a plurality of discrete portions vertically aligned to a middle vertical line of the source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of semiconductor nanostructures as a stack;
etching the plurality of semiconductor nanostructures to form a source/drain recess on a side of the plurality of semiconductor nanostructures, wherein the source/drain recess has a middle vertical line;
growing a first semiconductor layer from the plurality of semiconductor nanostructures, wherein the first semiconductor layer comprises a dopant of a conductivity type, and the conductivity type is p-type or n-type;
growing a second semiconductor layer over the first semiconductor layer, wherein the second semiconductor layer comprises a second dopant of the conductivity type, and wherein the second semiconductor layer comprises:
a vertical-and-elongated high-dopant region aligned to the middle vertical line, wherein the vertical-and-elongated high-dopant region extends to a bottom level lower than a bottom surface of a bottommost semiconductor nanostructure of the plurality of semiconductor nanostructures; and
a low-dopant region comprising portions on opposite sides of the vertical-and-elongated high-dopant region; and
forming a silicide region over and electrically coupling to the second semiconductor layer.

2. The method of claim 1 further comprising forming a capping layer contacting opposite gate spacers, wherein the capping layer has a lower doping concentration than the low-dopant region.

3. The method of claim 1, wherein the silicide region contacts a top end of the vertical-and-elongated high-dopant region.

4. The method of claim 1, wherein the vertical-and-elongated high-dopant region comprises a first plurality of discrete portions separated from each other by the low-dopant region.

5. The method of claim 4, wherein centers of the first plurality of discrete portions are horizontally aligned to middle lines of the plurality of semiconductor nanostructures, and wherein the middle lines are in middle between top surfaces and bottom surfaces of respective ones of the plurality of semiconductor nanostructures.

6. The method of claim 5, wherein the second semiconductor layer further comprises a second plurality of discrete portions that are separated from each other and separated from the first plurality of discrete portions by the low-dopant region, and wherein the second plurality of discrete portions have a higher doping concentrate than the first plurality of discrete portions.

7. The method of claim 1, wherein the second semiconductor layer is formed using a precursor comprising:
a first silicon-containing precursor having a first sticking coefficient; and
a second silicon-containing precursor having a second sticking coefficient smaller than the first sticking coefficient.

8. The method of claim 7, wherein the first silicon-containing precursor comprise silane, and the second silicon-containing precursor comprises dichlorosilane.

9. The method of claim 7, wherein a ratio of a first flow rate of the first silicon-containing precursor to a second flow rate of the second silicon-containing precursor is smaller than about 0.7.

10. The method of claim 1, wherein the second semiconductor layer comprises a first portion and a second portion grown toward each other, and wherein the method comprises:
before the first portion is merged with the second portion, conducting a dopant-containing precursor that comprises the second dopant with a first flow rate; and
at a time the first portion has merged with the second portion, start conducting the dopant-containing precursor with a second flow rate greater than the first flow rate.

11. The method of claim 10 further comprising:
before the first portion is merged with the second portion, conducting a silicon-containing precursor with a third flow rate; and
at the time the first portion has merged with the second portion, start conducting the silicon-containing precursor with a fourth flow rate lower than the first flow rate.

12. A method comprising:
forming a semiconductor stack comprising a plurality of semiconductor nanostructures;
forming a source/drain region comprising:
growing a first semiconductor layer; and
growing a second semiconductor layer over the first semiconductor layer, wherein the second semiconductor layer comprises a first plurality of portions and a second plurality of portions grown toward each other, and wherein the growing the second semiconductor layer comprises:
conducting a silicon-containing precursor with a first flow rate starting from a starting time the second semiconductor layer is grown;
conducting a dopant-containing precursor with a second flow rate starting from the starting time; and
at a time the first plurality of portions start to merge with the second plurality of portions, reducing the first flow rate and increasing the second flow rate; and
forming a silicide region over and contacting the second semiconductor layer.

13. The method of claim 12, wherein the silicon-containing precursor comprises:
a first silicon-containing precursor having a first sticking coefficient; and
a second silicon-containing precursor having a second sticking coefficient smaller than the first sticking coefficient, wherein the first silicon-containing precursor has a lower flow rate than the second silicon-containing precursor.

14. The method of claim 13, wherein a ratio of flow rates of the first silicon-containing precursor to the second silicon-containing precursor is smaller than about 0.7.

15. The method of claim 13, wherein the first silicon-containing precursor comprises silane, and the second silicon-containing precursor comprises dichlorosilane.

16. The method of claim 12, wherein the second semiconductor layer comprises:
a vertical-and-elongated high-dopant region aligned to a middle vertical line of the source/drain region, wherein the vertical-and-elongated high-dopant region extends to a bottom level lower than a bottom surface of a bottommost semiconductor nanostructure of the plurality of semiconductor nanostructures; and
a low-dopant region comprising portions on opposite sides of the vertical-and-elongated high-dopant region.

17. A method comprising:
forming a semiconductor stack comprising a plurality of semiconductor nanostructures;
forming a source/drain region on a side of the semiconductor stack, the source/drain region being formed by processes comprising:
epitaxially growing a first semiconductor layer; and
epitaxially growing a second semiconductor layer over the first semiconductor layer, wherein the second semiconductor layer comprises:
a plurality of discrete high-dopant regions aligned to a vertical line that is in the middle of the source/drain region; and
a low-dopant region, wherein in a cross-sectional view of the source/drain region, the low-dopant region encircles the plurality of discrete high-dopant regions;
a source/drain silicide region over and contacting the second semiconductor layer, wherein the source/drain silicide region is spaced apart from the first semiconductor layer; and
a source/drain contact plug over and contacting the source/drain silicide region.

18. The method of claim 17, and the plurality of discrete high-dopant regions extend from a first level of a topmost semiconductor nanostructure to a second level of a bottommost semiconductor nanostructure.

19. The method of claim 17, wherein the source/drain silicide region is in contact with one of the plurality of discrete high-dopant regions.

20. The method of claim 17, wherein the plurality of discrete high-dopant regions comprise phosphorous with an atomic percentage greater than about 4 percent.
